(19) United States
(12) Patent Application Publication
(10) Pub. No.: US 2014/0002195 A1
(43) Pub. Date: Jan. 2, 2014

(54) OPERATIONAL AMPLIFIER WITH LATCHING STATE SUPPRESSION

(71) Applicant: Aurelio Pellegrini, Vimercate (IT)

(72) Inventor: Aurelio Pellegrini, Vimercate (IT)

(73) Assignee: ACCENT S.P.A., Vimercate (IT)

(21) Appl. No.: 13/977,875

(22) PCT Filed: Dec. 29, 2011
(86) PCT No.: PCT/EP2011/074235

§ 371 Date: Sep. 18, 2013

(30) Foreign Application Priority Data
Dec. 29, 2010 (IT) M12010A002437

(51) Int. Cl. H03F 3/45

(52) U.S. Cl. CPC H03F 3/45179
USPC 330/261

(57) ABSTRACT

An embodiment of an amplifier circuit is proposed. The amplifier circuit includes an amplifier stage having at least one input terminal for receiving an input signal and at least one output terminal for providing an output signal being amplified with respect to the input signal. The amplifier circuit further includes a load stage of the amplifier stage, the load stage including at least one load node each one coupled with a corresponding one of the at least one output terminal. The amplifier circuit further includes a control block for providing a control signal to the load stage according to the output signal for regulating the output signal in feedback, and first biasing means for providing a first bias current to each load node through the amplifier stage. The load stage includes second biasing means for providing at least one second bias current to each load node and regulation means for providing a regulation current to each load node according to the control signal. In an embodiment, the amplifier stage includes separation means for replicating the first bias current into a separation current and for sinking the separation current from each load node, the amplifier circuit further including buffer means for providing a buffer current to each load node, the buffer current balancing the at least one second bias current and the regulation current at each load node.

### PRIORITY CLAIM

The present application is a national phase application filed pursuant to 35 USC §371 of International Patent Application Serial No. PCT/EP2011/074235, filed Dec. 29, 2011; which further claims the benefit of the U.S. Provisional Patent Application Ser. No. 61/427,894 filed Dec. 29, 2010, now expired; and further claims benefit of Italian Patent Application No. MI2010A002437, filed Dec. 29, 2010, all of the foregoing applications are incorporated herein by reference in their entireties

### TECHNICAL FIELD

One or more embodiments generally relate to the electronics field. More specifically, one or more embodiments relate to amplifier circuits.

### SUMMARY

Amplifier circuits are electronic circuits widely used in applications wherein it is necessary to amplify signals for allowing a proper subsequent processing thereof (e.g., filtering, conversion, or the like).

A very widespread class of amplifier circuits is represented by fully differential operational amplifiers, which generally include an amplifier stage for receiving a differential input signal and providing a differential output signal being amplified with respect to the input signal (which will be referred to as operational amplifiers in the following for the sake of simplicity).

Since such operational amplifiers are implemented by configurations having a high degree of symmetry, they usually are able to ensure high performance in terms of gain, bandwidth, and common mode noise rejection.

As it is known, since in operational amplifiers each variable component of the input signal is symmetrical with respect to a common mode input signal whereas each variable component of the output signal is symmetrical with respect to a common mode output signal not depending on the common mode input signal, such operational amplifiers are typically provided with a common-mode feedback block (or CMFB, “Common Mode FeedBack”) for regulating the common mode output signal at a desired value that avoids saturation conditions.

In a typical implementation of the CMFB block, the common mode output signal is withdrawn, by a divider (e.g., of a resistive and/or capacitive type), and compared, for example, by a comparator, to the desired value; according to a result of such comparison, the comparator provides a corresponding control signal for regulating the common mode output signal.

Operational amplifiers have some drawbacks that preclude a wider use thereof, substantially due to certain limitations introduced by the CMFB block.

First of all, the CMFB block introduces a feedback loop relative to the common mode output signal within the operational amplifier (hereinafter referred to as common mode loop for distinguishing it from a differential loop relative to the variable component of the input signal and the variable component of the output signal); such common mode loop introduces an additional pole involving relatively complex stability problems of the operational amplifier as a whole.

In addition, the CMFB block may also cause malfunctions of the operational amplifier when the latter is in certain undesired operating conditions; for example, in a latching state condition, i.e., wherein the common mode input signal reaches values such as to turn off the amplifier stage of the operational amplifier, the CMFB block stops working properly and saturates the output signal, sometimes irreversibly, to an upper supply voltage (e.g., positive, such as 3.3 V) or a lower supply voltage (e.g., negative, such as −3.3 V, or zero).

In the state of the art some solutions exist that try to solve the stability problems due to the CMFB block and/or the malfunctions introduced by the latter in latching state conditions.

For example, some design approaches provide for a gain and/or bandwidth reduction of the CMFB block in order to obtain a stable common mode loop. However, a reduced gain of the CMFB block may involve an inefficient control of the common mode output signal, which degrades accuracy and repeatability of the output signal of the operational amplifier. Moreover, a reduced bandwidth of the CMFB block may involve intense and prolonged transients of the common-mode output signal, which may be detrimental in applications wherein the operational amplifier is functionally coupled with circuits that provide for high-speed switching (e.g., switched capacitor circuits). In addition, in case of a relatively high output signal, and such as, for example, to saturate the operational amplifier immediately, an excessive duration of the transients may involve a slow rearrangement of the output signal, thereby causing a prolonged distortion thereof.

In some solutions, such as, for example, the one shown in US-A-2007/0188231, which is incorporated by reference, the latching state condition is avoided thanks to the use of an operational amplifier having a folded-cascode architecture, and by setting design constraints on some bias currents. Such solution, however, has a low versatility, since it is not applicable with acceptable results to other architectures of operational amplifiers; moreover, the common mode loop has a reduced bandwidth, which involves a worse dynamic behavior of the operational amplifier.

Instead, in Banu et al. “Fully Differential Operational Amplifiers with Accurate Output Balancing”, IEEE Journal of Solid-State Circuits, Vol 23, No. 6, December 1988, pp. 1410-1414, which is incorporated by reference, the stability problem has been addressed by implementing the CMFB block in feed-forward configuration; in this way, in the transfer function of the common mode loop a zero is introduced close to the additional pole, so as to obtain compensation of the latter and to improve stability of the operational amplifier. Moreover, the saturation to which the operational amplifier is subject in a latching state condition is avoided thanks to a marked imbalance of the CMFB block; in fact, after the shutdown of the amplifier stage (or part thereof), the CMFB block provides an additional current for compensating the current no longer supplied by the amplifier stage, which involves a relatively large error on the output common mode signal. However, even such solution is not very versatile, as it involves implementation drawbacks when using the same in operational amplifiers having a different architecture; for example, when using the same solution in a folded-cascode architecture, in order to prevent the latching state it would be necessary to use an output stage of the operational amplifier based on a MOS transistor in voltage follower configuration, instead of a high performance structure (for example, a push-pull structure); this would involve a small gain of both the common mode loop and the differential loop (with the drawbacks described above) and a worsening of output swing (minimum achievable output signal) of the operational amplifier, which would make the use thereof difficult in low voltage applications.

In its general terms, one or more embodiments are based on the idea of separating the bias currents of the amplifier stage.

In particular, one or more embodiments are set out in the independent claims, with advantageous features of the same embodiment that are indicated in the dependent claims, whose wording is enclosed herein verbatim by reference (with any advantageous feature provided with reference to an embodiment that applies mutatis mutandis to any other aspect thereof).

More specifically, an embodiment is an amplifier circuit (for example, a fully-differential operational amplifier). The amplifier circuit includes an amplifier stage (for example, having two gain stages) having at least one input terminal for receiving an input signal (for example, a differential input signal) and at least one output terminal for providing an output signal (for example, a differential output signal) being amplified with respect to the input signal. The amplifier circuit further includes a load stage (for example, an active load) of the amplifier stage, the load stage including at least one load node each one coupled with a corresponding one of the at least one output terminal. The amplifier circuit further includes a control block (for example, a common mode feedback block) for providing a control signal (for example, a control voltage or current) to the load stage according to the output signal for regulating the output signal in feedback. First biasing means are provided for providing a first bias current to each load node through the amplifier stage. The load stage includes second biasing means for providing at least one second bias current to each load node and regulation means for providing a regulation current to each load node according to the control signal. In an embodiment, the amplifier stage includes separation means for replicating the first bias current into a separation current and for sinking the separation current from each load node. The amplifier circuit further includes buffer means for providing a buffer current to each load node, the buffer current balancing the at least one second bias current and the regulation current at each load node.

Another embodiment is a complex electronic system including said amplifier circuit.

Another embodiment is a corresponding method.

### BRIEF DESCRIPTION OF THE DRAWINGS

One or more embodiments, as well as features and the advantages thereof, will be best understood with reference to the following detailed description, given purely by way of a non-restrictive indication, to be read in conjunction with the accompanying drawings (wherein corresponding elements are denoted with equal or similar references, and their explanation is not repeated for the sake of exposition brevity). In particular:

FIG. 1 schematically shows an amplifier circuit known in the state of the art wherein one or more embodiments may be applied.

FIG. 2 schematically shows an amplifier circuit, according to an embodiment.

FIGS. 3-5 show circuit solutions of the amplifier circuit of FIG. 2, according to corresponding embodiments.

### DETAILED DESCRIPTION

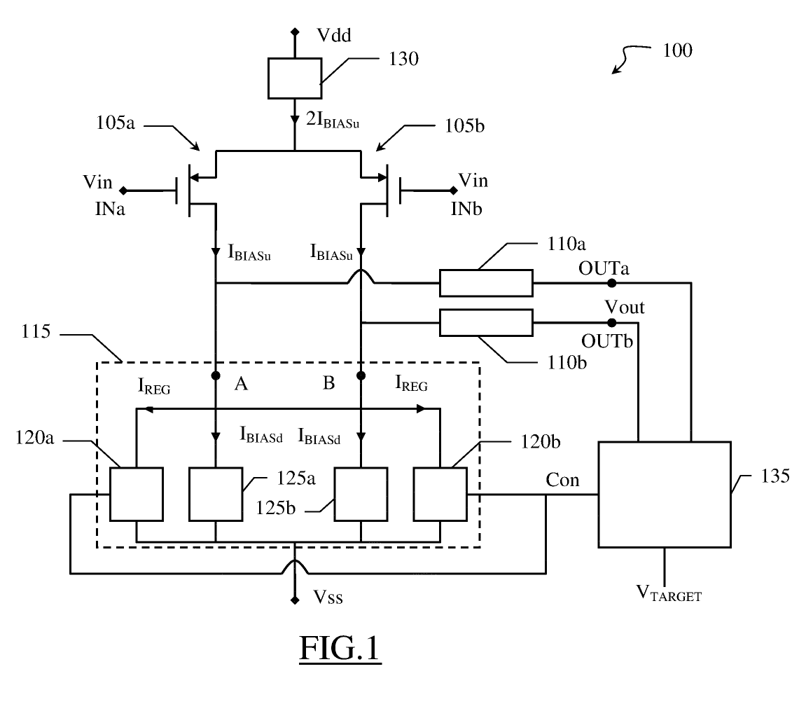

With particular reference to FIG. 1, it schematically shows an amplifier circuit known in the state of the art wherein one or more embodiments may be applied. More specifically, in the exemplary but not limiting described embodiment, the amplifier circuit is implemented by an operational amplifier (e.g., a fully differential operational amplifier) 100.

Regardless of the used operational amplifier architecture, the operational amplifier 100 typically includes an amplifier stage with a symmetrical structure; for this reason, in the following of the present description, replicated functional elements of the amplifier stage will be denoted by same number references but differentiated through the letters a and b, respectively.

The amplifier stage includes an input stage for receiving a differential input signal Vin to be amplified. More particularly, the input stage includes an input transistor 105a (e.g., of P-channel MOS type) having a source terminal, a drain terminal and a gate terminal, and another input transistor 105b equal to the transistor 105a; the transistors 105a, 105b are coupled to each other in differential configuration, i.e., with the source terminal of the transistor 105a that is coupled to the source terminal of the transistor 105b, and with the signal Vin that is applied across the gate terminals of the transistors 105a, 105b (thus implementing corresponding input terminals INa,INb of the operational amplifier 100).

The amplifier stage also includes two output stages 110a and 110b coupled with the drain terminals of the transistors 105a and 105b, respectively, for providing, through corresponding output terminals OUTa and OUTb, a differential output signal Vout amplified with respect to the signal Vin.

The amplifier stage also includes a load stage 115, which generally performs biasing and, at the same time, active load functions; in fact, the input stage 105a, 105b and the load stage 115 implement a first gain stage of the amplifier stage whereas the output stage 110a, 110b implements a second gain stage of the amplifier stage.

The load stage 115 includes a load node A,B coupled with the drain terminal of the transistor 105a, 105b. Typically, the load stage 115 may be made according to different implementations according to corresponding operational amplifier architectures; however, being the implementation of the load stage 115 not limitative for this disclosure, it will be schematically described in terms of elements being functionally common to substantially all the architectures.

In particular, the load stage 115 includes a regulation element 120a, 120b, which is coupled between the node A,B and a supply terminal providing a lower supply voltage Vss (e.g., a ground voltage), or terminal Vss; the regulation element 120a, 120b is controlled by a control signal Con (for example, a control voltage or a control current) such as to cause a regulation current I_{REG} (e.g., variable according to the control signal Con) to flow through it (and thus through the node A,B). The load stage 115 also includes a bias current generator, or lower tail generator, 125a, 125b, which is coupled between the node A,B and the terminal Vss; the lower tail generator 125a, 125b provides a bias current I_{BIASu}, to the node A,B.

The operational amplifier 100 includes a further bias current generator, or upper tail generator, 130 coupled between a further supply terminal providing an upper supply voltage Vdd (e.g., Vdd=3.3 V with respect to the ground voltage), or terminal Vdd, and the source terminal of the transistor 105a, 105b for providing a bias current 2I_{BIASu} to the first gain stage 105a, 105b, 115 of the amplifier stage; in particular, given the symmetry of the amplifier stage, each transistor 105a, 105b is biased by a bias current I_{BIASu}, equal to half the current 2I_{BIASu}, flowing to the node A,B through the amplifier stage. In this way, in steady state conditions, the first gain stage 105a, 105b, 115 is biased in such a way that the current I_{BIASu} is equal to a combination of the current I_{BIASd} and the current I_{REG}. More specifically, according to the exemplary current direction shown in the figure, the following equation should be satisfied at the node A,B:

I_{BIASu}=I_{BIASd}+I_{REG}

The operational amplifier 100 also includes a common-mode feedback block (or CMFB block) 135 coupled between the output stage 110a, 110b and the load stage 115. In general, the CMFB block 135 acts as a control element for the regulation element 120a, 120b. More in particular, the CMFB block 135 is coupled to the terminals OUTa and OUTb for receiving the signal Vout, from which it derives a corresponding measurement signal V_{MIS} depending thereon (for example, a common mode signal thereof obtained through a resistive and/or switched capacitive partition network, not shown); the CMFB block 135 also receives a target signal V_{TARGET} to which it is desired to adjust the signal V_{MIS}, and provides the signal Con to the regulation element 120a, 120b according to a comparison between the signal V_{MIS} and the signal V_{TARGET}. In this way, the CMFB block 135, the regulation element 120a, 120b and the output stage 110a, 110b implement a common-mode feedback loop (or common mode loop) for controlling the common mode signal associated with the signal Vout.

As outlined in the introductory part of the present disclosure, the CMFB block 135, beside introducing an additional pole in the transfer function of the common-mode loop of the operational amplifier 100 (which involves stability problems), may cause malfunctions in “latching state” condition. In such condition, in fact, for effect of the turning off of the transistor 105a, 105b, and/or of the upper tail generator 130 (e.g., due to a high common mode input signal), a zeroing of the current I_{BIASu} in the first gain stage 105a, 105b, 115 occurs. In this way, the node A,B does not receive the current I_{BIASu} any longer, and the CMFB block 135, keeping on withdrawing the current I_{REG} therefrom, causes the voltage at the node A,B to decrease down to the voltage Vss; this may in turn saturate the signal Vout up to the voltage Vdd or down to the voltage Vss, thereby practically losing the control over the common mode signal; this leads the operational amplifier 100 to undesired operating conditions (e.g., a block condition)—that may last even after the latching state condition has ended; in such conditions the operational amplifier 100 is latched in a malfunctioning state.

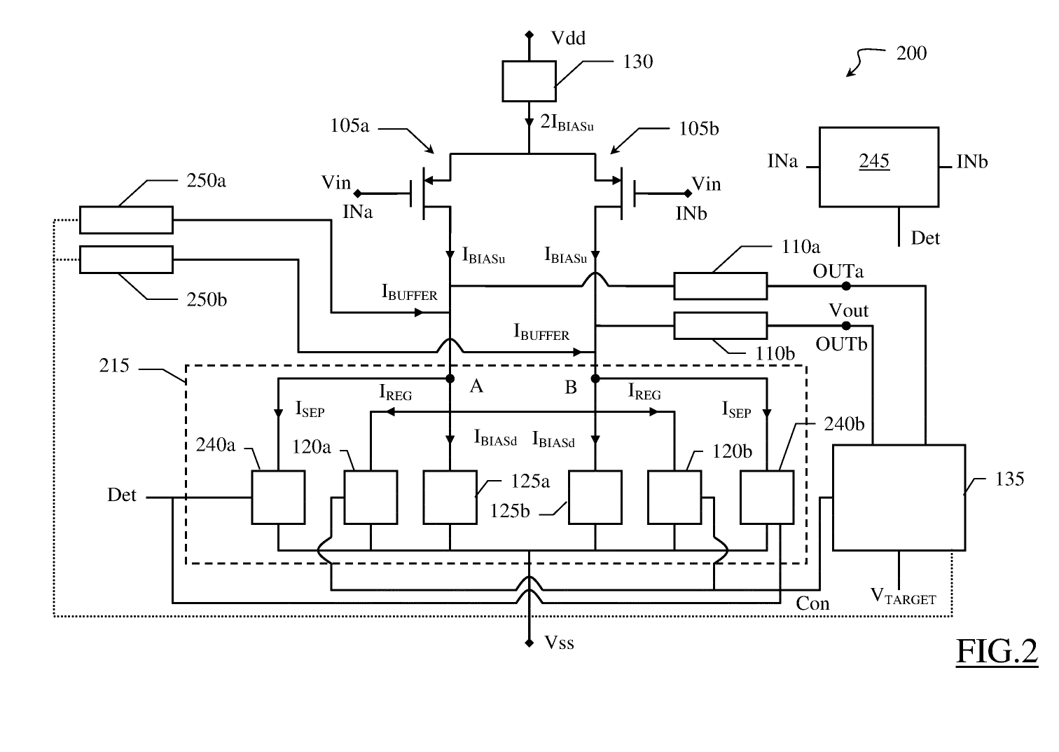

Turning now to FIG. 2, there is schematically shown an operational amplifier 200 according to an embodiment. The operational amplifier 200 includes the input transistor 105a, 105b, the output stage 110a, 110b, the upper tail generator 130, and the CMFB block 135 as above.

The operational amplifier 200 includes a load stage 215 still including the regulation element 120a, 120b and the lower tail generator 125a, 125b, but it also includes a separation block 240a, 240b coupled between the node A,B (and hence coupled with the drain terminal of the transistor 105a, 105b), and the terminal Vss; the separation block 240a, 240b receives a detection signal Det (for example, a detection current, as described in the following) and, according to such signal, sinks a separation current I_{SEP} equal to the current I_{BIASu} from the node A,B (by separating it, in the load stage 215, from the currents I_{BIASd} and I_{REG}). In order to achieve that, as will be better described in the following when disclosing preferred (but not limiting) implementations of the operational amplifier 200, the separation block 240a, 240b may be generally configured for substantially replicating or reproducing (e.g., mirroring) the current I_{BIASu} into the current I_{SEP} (i.e., the current I_{SEP} matches the current I_{BIASu} at the node A,B).

Moreover, the operational amplifier 200 includes a detection block 245 for detecting a zeroing condition of the current I_{BIASu} (i.e., a latching state condition) and providing the corresponding signal Det indicative of the detected condition to the separation block 240a, 240b.

Finally, the operational amplifier 200 includes a buffer block 250a, 250b, which is coupled with the node A,B so as to provide the latter with a buffer current I_{BUFFER} that balances the current I_{BIASd} and the current I_{REG} (e.g., by automatically adjusting according to variations of the current I_{REG}, as better described below).

In this way, for the current I_{BIASu} a first functional path is defined between the transistor 105a, 105b and the separation block 240a, 240b, whereas for the current I_{BIASd} a second functional path is defined among the buffer block 250a, 250b, the regulation element 120a, 120b and the lower tail generator 125a, 125b. As visible in the figure, the buffer block 250a, 250b is coupled to the CMFB block 135 by a dotted line; such notation is intended to indicate, as will be explained in more detail in the following description of exemplary embodiments, that the buffer block 250a, 250b may be coupled or not with the CMFB block 135 (so as to obtain different dependencies of the buffer current I_{BUFFER}).

The operating principle of the operational amplifier 200 may be summarized as follows.

In the case of normal operation of the operational amplifier 200 (current I_{BIASu} at the node A,B being not zero), the signal Det is such that the separation block 240a, 240b is crossed by the current I_{SEP} equal to the current I_{BIASu} (first functional path being active), with the second functional path that is active too (and crossed by the buffer current I_{BUFFER} and the currents I_{BIASd} and I_{REG}). As soon as the detection block 245 detects the zeroing of the current I_{BIASu}, the signal Det becomes such that the separation block 240a, 240b turns off (thus disabling the first functional path); instead, the second functional path remains active, so that the CMFB block 135, being not affected by any bias change (since the current I_{REG} keeps on flowing across the second functional path), it works correctly (thus avoiding causing malfunctions to the operational amplifier 200).

The described embodiment may be advantageous since it allows protecting, in presence of latching state condition, the CMFB block 135 (and thus the operational amplifier 200) from malfunctions (and regardless of a duration of the latching state).

It is noted that in case the load stage 215 includes further functional blocks that provide corresponding further currents, in addition to the currents I_{BIASd} and I_{REG}, the principles of the present disclosure are still valid as it is sufficient to ensure that the current I_{BUFFER} balances, in addition to the currents I_{BIASd} and I_{REG}, such further currents as well.

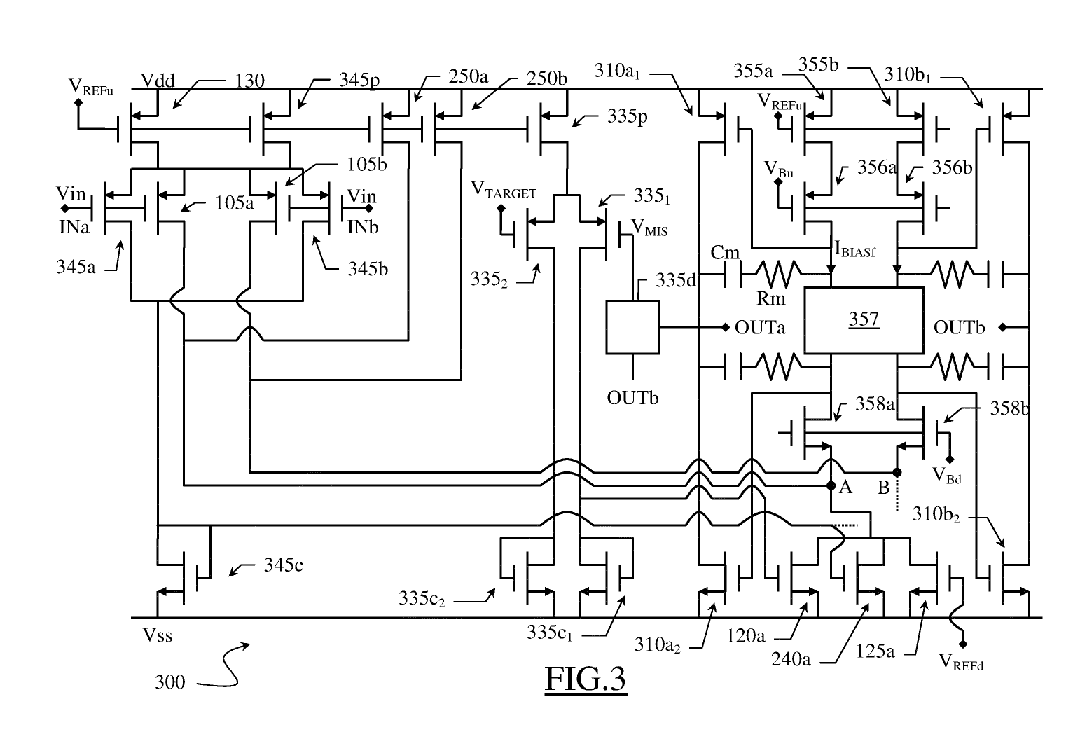

FIGS. 3-5 show some circuit implementations of the operational amplifier of FIG. 2 according to corresponding embodiments. In this respect, it is noted that the embodiments described below are to be construed in an exemplary and not limiting way, as intended to simply show that the embodiments may be applied, with a few simple circuit expedients, to substantially any operational amplifier architecture (for obtaining corresponding further benefits in addition to that of protection of the CMFB block).

With particular reference to FIG. 3, it shows an operational amplifier 300 according to an embodiment. More specifically, the operational amplifier 300 implements a so-called folded-cascode architecture.

As visible in the figure, the upper tail generator 130 is implemented by a tail transistor (e.g., of the P-channel MOS type), denoted by the same reference for the sake of simplicity. The transistor 130 includes a source terminal coupled to the terminal Vdd, a gate terminal receiving a reference voltage V_{REFu}, and a drain terminal coupled to the source terminals of both the transistors 105a and 105b.

The output stage of the operational amplifier 300 includes a class AB block of a known type, including a P-channel MOS transistor 310a₁,310b₁ and an N-channel MOS transistor 310a₂,310b₂ coupled in series with the transistor 310a₁,310b₁; in particular, the source terminal of the transistor 310a₁,310b₁ and the source terminal of the transistor 310a₂,310b₂ are coupled to the terminal Vdd and to the terminal Vss, respectively, whereas the drain terminal of the transistor 310a₁,310b₁ is coupled to the drain terminal of the transistor 310a₂,310b₂.

Moreover, the operational amplifier 300 includes four identical compensation networks (each one including a resistor Rm and a capacitor Cm); each network Rm,Cm is coupled between the gate terminal and the drain terminal of a respective transistor 310a₁,310b₁,310a₂,310b₂ for performing a frequency compensation by Miller effect.

The load stage of the operational amplifier 300 also includes, in addition to the regulation element 120a, 120b, the lower tail generator 125a, 125b and the separation block 240a, 240b (with the regulation element 120b, the lower tail generator 125b and the separation block 240b that, although not shown in the figure for the sake of representation simplicity, have analogous couplings to the node B as the regulation element 120a, the lower tail generator 125a and the separation block 240a have to the node A), a further upper tail generator 355a, 355b (implemented by a P-channel MOS transistor) for providing a further bias current I_{BIASf}, a P-channel MOS transistor in cascode configuration (or cascoded transistor) 356a, 356b (e.g., of P-channel MOS type), a control block 357 of the class AB block 310a₁,310b₁,310a₂,310b₂, and another cascoded N-channel MOS transistor 358a,358b (e.g., of N-channel MOS type); in particular, the drain terminal of the upper tail generator 355a, 355b is coupled to the source terminal of the transistor 356a, 356b, whereas the drain terminals of the transistor 356a, 355b and of the transistor 358a,358b are coupled to the control block 357 (and coupled with the gate terminals of the transistor 310a₁,310b₁ and of the transistor 310a₂,310b₂, respectively). Finally, the source terminal of the transistor 358a,358b is coupled to the node A,B, whereas the gate terminal of the transistor 356a, 356b and the gate terminal of the transistor 358a,358b are coupled to a terminal that provides a fixed voltage V_{Bu} (or terminal V_{Bu}) and to another terminal that provides another fixed voltage V_{Bd} (or terminal V_{Bd}), respectively.

The lower tail generator 125a, 125b is implemented by an N-channel MOS transistor, denoted by the same reference for the sake of simplicity, which includes a drain terminal coupled to the node A,B, a source terminal coupled to the terminal Vss, and a gate terminal that receives another reference voltage V_{REFd}.

The CMFB block includes a partition network 335d for receiving the signal Vout from the terminals OUTa and OUTb and providing the signal V_{MIS} (e.g., the common mode output signal, equal to the mean value of the signal Vout), a section 335₁ for receiving the signal V_{MIS}, another section 335₂ for receiving the signal V_{TARGET}, and a bias section 335p (implemented like the upper tail generator 130) coupled to the section 335₁,335₂ for biasing it. In particular, the section 335₁ and the section 335₂ implement a differential stage for providing the (current) signal Con according to a difference between the signal V_{MIS} and the signal V_{TARGET}. Moreover, the CMFB block includes a load element 335c₁,335c₂ for the section 335₁,335₂, implemented by an N-channel MOS transistor in diode-coupled configuration (i.e., with a gate terminal and a drain terminal short-circuited to each other, and a source terminal coupled to the terminal Vss); the transistor 335c₁ also acts as a coupling element for coupling the section 335₁ with the regulation element 120a, 120b, so as to set the current I_{REG} through it according to the current Con; in particular, the transistor 335c₁ implements a reference branch of a current mirror 335c₁,120a, 120b, whereas the regulation element 120a, 120b implements an operative branch of the current mirror 335c₁,120a, 120b coupled with the node A,B; more specifically, as visible in the figure, the regulation element 120a, 120b is implemented by an N-channel MOS transistor (denoted by the same reference for the sake of simplicity) having a drain terminal coupled to the node A,B, a source terminal coupled to the terminal Vss, and a gate terminal coupled to the drain terminal of the transistor 335c₁.

The detection block includes two P-channel MOS detection transistors 345a and 345b; the gate terminal of the transistor 345a, 345b is coupled to the terminal INa,INb for receiving the signal Vin, whereas the drain terminal and the source terminal of the transistor 345a are coupled to the drain terminal and to the source terminal, respectively, of the transistor 345b. The detection block also includes another upper tail generator 345p (analogous to the upper tail generator 130) for providing the current 2I_{BIASu} to the source terminal of the transistor 345a, 345b, and a further coupling element 345c (implemented by an N-channel MOS transistor in diode-coupled configuration) for coupling the drain terminal of the transistor 345a, 345b with the separation block 240a, 240b (so as to set the current I_{SEP} according to the current Det, equal to 2I_{BIASu} in the example at issue). It is noted that in the operational amplifier 300 the source terminal of the transistor 345a, 345b is also coupled to the source terminal of the transistor 105a, 105b and that the drain terminal of the transistor 345p is further coupled to the drain terminal of the transistor 130; this allows a more compact implementation of an embodiment without penalizing the operation thereof (even if such couplings are not strictly necessary and the operation of the detection block may be understood with reference to the above description).

As in the case of the CMFB block, the coupling element 345c implements a reference branch of a further current mirror 345c,240a, 240b, whereas the separation block 240a, 240b implements a further operative branch of the current mirror 345c,240a, 240b being coupled with the node A,B (with the reference branch 240a, 240b, that is implemented in the same way as the reference branch 120a, 120b).

Finally, the buffer block is implemented by a buffer P-channel MOS transistor 250a, 250b (denoted by the same reference for the sake of simplicity); the drain terminal of the transistor 250a, 250b is coupled to the node A,B, whereas the source terminal and the gate terminal are coupled to the terminal Vdd and to the terminal V_{REFu}, respectively. As the transistor 250a, 250b and the transistor 125a, 125b are coupled in series to each other, the current I_{BUFFER}, under proper design settings (e.g., sizing of the transistors 250a, 250b and 125a, 125b), substantially follows any variations of the current I_{REG}.

In this way, it is possible to write the following balance equation at the node A,B:

I_{BUFFER}+I_{BIASu}+I_{BIASf}=I_{BIASd}+I_{REG}+I_{SEP}

Therefore, through a simple sizing of the operational amplifier 300, it is possible to obtain

I_{SEP}=I_{BIASu}

I_{BUFFER}+I_{BIASf}=I_{BIASd}+I_{REG}

The described embodiment is advantageous in that, besides protecting the CMFB block from malfunctions in the latching state condition, it allows obtaining advantages deriving from the use of the folded-cascode architecture (high output swing and high gain) as well.

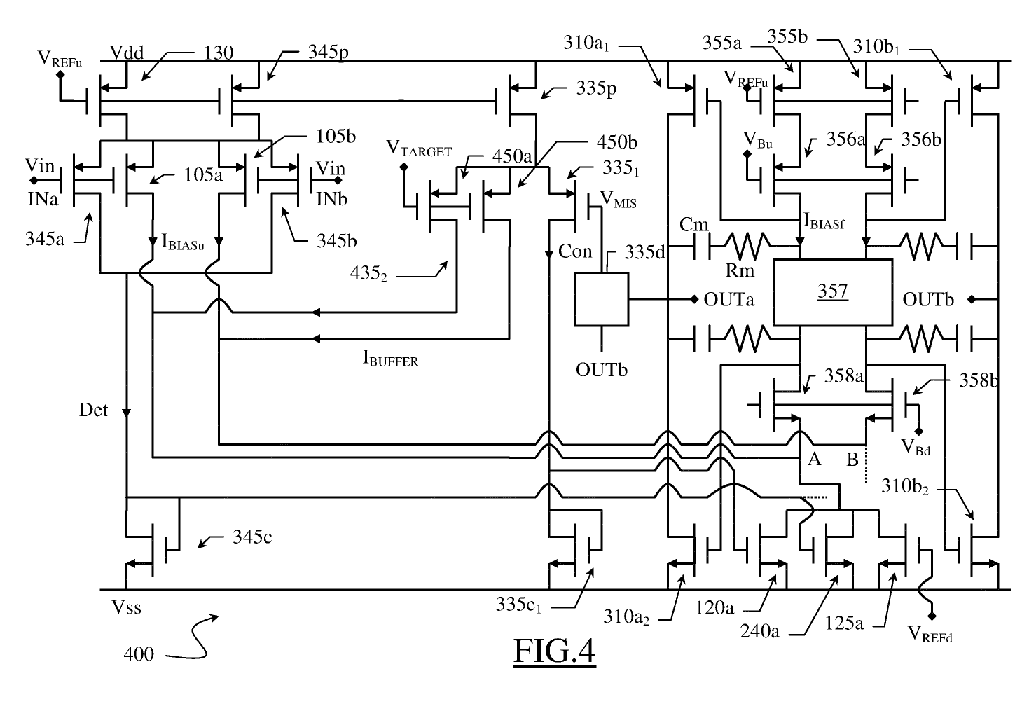

Turning now to FIG. 4, it shows an operational amplifier 400 according to another embodiment. The operational amplifier 400 has a structure very similar to that of the previous operational amplifier, but differs from the latter for the fact that the buffer block and the CMFB block are coupled with each other for cooperating.

In particular, the CMFB block still includes the bias section 335p, the partition network 335d, the coupling element 335c₁, the section 335₁ and a section 435₂, which now includes the buffer block.

The buffer block includes two buffer transistors 450a and 450b, analogous to the transistors 250a and 250b, but with the source terminal coupled with the section 335₁, the drain terminal coupled to the node A,B, and the gate terminal that receives the signal V_{TARGET}.

In this way, the buffer block 450a, 450b provides the current I_{BUFFER} to the node A,B directly depending on the current that defines the signal Con (in the specific illustrated embodiment, each transistor 450a, 450b is crossed by half the current Con that flows within the section 335₁).

Therefore, the balance equation at the node A,B is still the following:

I_{BUFFER}+I_{BIASu}+I_{BIASf}=I_{BIASd}+I_{REG}+I_{SEP}

As before, the sizing of the operational amplifier 400 will be such that

I_{BIASu}=I_{SEP}

Furthermore, assuming, for example, a mirroring ratio equal to ½ for the current mirror 345c,240a, 240b, it follows that

hd REG=I_{BUFFER}

and, as a consequence, it will be sufficient to set

I_{BIASf}=I_{BIASd}

The described embodiment is further advantageous as it allows obtaining a high control of the current I_{BUFFER} (depending, the latter, directly on the current Con); this ensures high gain and bandwidth of the common mode loop, which translates into a better swing behavior of the operational amplifier.

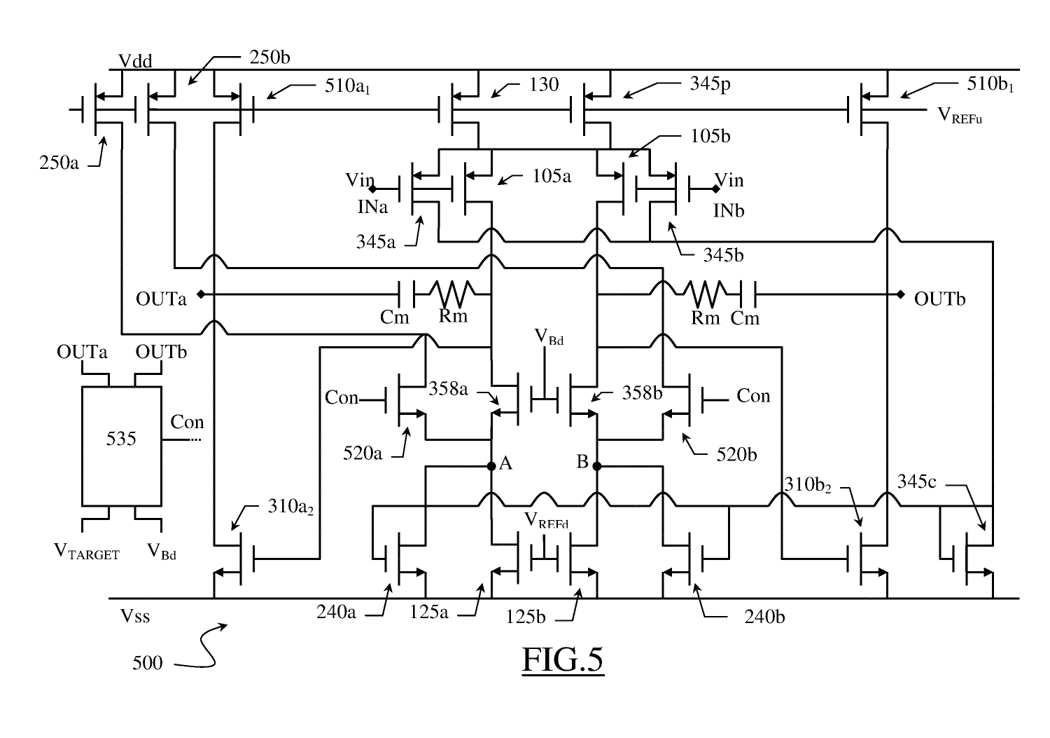

With reference now to FIG. 5, an operational amplifier 500 according to another embodiment is shown. More particularly, the operational amplifier 500 is in an architecture being called “telescopic”.

The operational amplifier 500 includes the upper tail generator 130, the buffer block 250a, 250b, the detection block 345a, 345b, 345p,345c and two compensation networks Rm,Cm as above; in this case, the operational amplifier 500 includes a different output stage, load stage, and a CMFB block 535.

In particular, the output stage includes the transistor 310a₂,310b₂ and a further upper tail generator 510a₁,510b₁ analogous to the upper tail generator 130 but with the drain terminal coupled to the drain terminal of the transistor 310a₂,310b₂. In this way, the transistor 310a₂,310b₂ implements a configuration called common source.

The load stage includes the separation block 240a, 240b, coupled, as in the foregoing, with the detection block 345a, 345b, 345p,345c through the coupling element 345c thereof, the lower tail generator 125a, 125b coupled to the node A,B, the transistor 358a,358b having the source terminal coupled to the node A,B, the gate terminal coupled to the terminal V_{Bd}, and the drain terminal coupled to the drain terminal of the transistor 105a, 105b and to the gate terminal of the transistor 310a₂,310b₂, and a regulation block 520a, 520b.

The regulation block 520a, 520b includes a differential transistor, 520a, 520b (e.g., of N-channel MOS type, and denoted by the same reference for the sake of simplicity) having a source terminal coupled to the node A,B, a drain terminal coupled to the drain terminal of the transistor 250a, 250b, and a gate terminal for receiving the signal Con. The transistor 520a, 520b and the transistor 358a,358b implement, as a matter of fact, a corresponding differential stage that receives the signal Con and the signal V_{Bd} and provides the signal I_{REG} according to a difference between the signal Con and the signal V_{Bd}; in this way, the transistor 250a, 250b and the transistor 520a, 520b are crossed by the current I_{BUFFER} equal to the (current) signal I_{REG}. Moreover, the differential stages 520a, 358a and 520b, 358b introduce an additional inversion in the transfer function of the feedback loop of the CMFB block 535 (so as to compensate the inversion introduced by the common source output stage).

The CMFB block 535 is implemented by a switched capacitor circuit (e.g., that described in David Jones, Ken Martin, “Analog Integrated Circuit Design”, Wiley, pagg. 287,291, not shown in the figure for the sake of simplicity, but which is incorporated by reference), which receives the signals Vout, V_{TARGET}, V_{Bd} and provides the (voltage) signal Con to the gate terminal of the transistor 520a, 520b.

The balance equation at the node A,B is now the following:

I_{BUFFER}+I_{BIASu}=I_{BIASd}+I_{SEP}

As before, the sizing of the operational amplifier 500 will be such that

I_{BIASu}=I_{SEP}

I_{BUFFER}=I_{BIASd}

The described embodiment is advantageous since it is applicable to an architecture of operational amplifier that provides for an output stage implemented by a transistor in common source configuration.

Naturally, in order to satisfy local and specific requirements, a person skilled in the art may apply to the one or more embodiments described above many logical and/or physical modifications and alterations. More specifically, although one or more embodiments have been described with a certain degree of particularity, it is to be understood that various omissions, substitutions and changes in the form and details as well as other embodiments are possible. In particular, different embodiments may even be practiced without the specific details (such as the numeric examples) set forth in the preceding description for providing a more thorough understanding thereof; on the contrary, well known features may have been omitted or simplified in order not to obscure the description with unnecessary particulars. Moreover, it is expressly intended that specific elements and/or method steps described in connection with any disclosed embodiment may be incorporated in any other embodiment as a matter of general design choice.

Analogous considerations apply if the operational amplifier has a different structure or includes equivalent components, or it has other operating features. In any case, any component thereof may be separated into several elements, or two or more components may be combined into a single element; moreover, each component may be replicated for supporting the execution of the corresponding operations in parallel. It should also be noted that any interaction between different components generally does not need to be continuous (unless otherwise indicated), and it may be both direct and indirect through one or more intermediaries.

Moreover, although explicit reference has been made to an operational amplifier with two gain stages, nothing prevents implementing an embodiment of an operational amplifier with three (or more) gain stages, or with a single gain stage. In addition, an embodiment may also be applied to single-ended operational amplifiers (i.e., with non-differential signals), or to any other amplifier circuit.

The same considerations are valid if the control block implements a control circuit for regulating a different parameter (i.e., not necessarily the common mode output signal). Additionally or alternatively, the detection block may detect a different condition of the operational amplifier.

Moreover, although in the exemplary described embodiments reference has been made to operational amplifiers with PMOS-based input stage (and respective structure coupled thereto with such PMOS and/or NMOS transistors to ensure the proper operation of the operational amplifier), nothing prevents implementing the described embodiments (or other ones ascribable thereto) by dual configurations (i.e., with the input stage made by NMOS transistors, and respective structure being opposite to the previous one).

In general, the detection block, the lower and upper tail generators, and the regulation element may be made in any other equivalent manner, according to design parameters (deriving, for example, from economic considerations and/or performance to be obtained).

It is to be readily understood that an embodiment of the proposed structure may be part of the design of an integrated circuit. The design may also be created in a programming language; moreover, if the designer does not manufacture the electronic devices or the masks, the design may be transmitted by physical means to others. In any case, the resulting integrated circuit may be distributed by its manufacturer in raw wafer form, as a bare die, or in packages. Moreover, the proposed structure may be integrated with other circuits in the same chip, or it may be mounted in intermediate products (such as mother boards) and coupled with one or more other chips (such as a processor). In any case, the integrated circuit is suitable to be used in complex systems (such as automotive applications or microcontrollers).

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

1. An amplifier circuit comprising:
an amplifier stage having at least one input terminal for receiving an input signal and at least one output terminal for providing an output signal being amplified with respect to the input signal,
a load stage of the amplifier stage, the load stage comprising at least one load node each one coupled with a corresponding one of the at least one output terminal,
a control block for providing a control signal to the load stage according to the output signal for regulating the output signal in feedback,
first biasing means for providing a first bias current to each load node through the amplifier stage,
the load stage comprising second biasing means for providing at least one second bias current (I_{BIASd},I_{BIASf}) to each load node and regulation means for providing a regulation current (I_{REG}) to each load node according to the control signal,
wherein the amplifier stage comprises separation means for replicating the first bias current into a separation current and for sinking the separation current from each load node, the amplifier circuit further comprising buffer means for providing a buffer current to each load node, the buffer current balancing the at least one second bias current and the regulation current at each load node.

2. The amplifier circuit according to claim 1, further comprising detection means for detecting a zeroing condition of the first bias current and for disabling the separation means in response to the zeroing of the first bias current.

3. The amplifier circuit according to claim 2, wherein the detection means comprises, for each input terminal:
at least one detection transistor having a first conduction terminal, a second conduction terminal and a control terminal, the control terminal of the detection transistor being coupled to the corresponding input terminal,
further first biasing means for providing a further first bias current to the first conduction terminal of the detection transistor, and
coupling means for coupling the second conduction terminal of the detection transistor with the separation means for setting the separation current according to the further first bias current and to the corresponding input signal.

4. The amplifier circuit according to claim 3, wherein the coupling means comprises a reference branch of a current mirror being coupled with the second conduction terminal of the detection transistor for receiving a detection current corresponding to the further first bias current, and wherein the separation means comprises at least one operative branch of the current mirror each one being coupled with a corresponding load node.

5. The amplifier circuit according to claim 1, wherein
the control block comprises a differential block having a first differential section for receiving a measure signal depending on the output signal, and a second differential section for receiving a target signal indicative of a target value of the measure signal, the first differential section and the second differential section cooperating for providing a control current; defining the control signal according to a difference between the measure signal and the target signal, and wherein
the amplifier circuit comprises a further reference branch of a further current mirror coupled with one between the first differential section and the second differential section for providing the control current, and the regulation means comprises at least one further operative branch of the further current mirror each one coupled with a corresponding load node.

6. The amplifier circuit according to claim 1, wherein the buffer means comprises at least one buffer transistor having a first conduction terminal, a second conduction terminal and a control terminal, the second conduction terminal of the buffer transistor being coupled to a respective load node, the first conduction terminal of the buffer transistor being coupled to a supply terminal for receiving a supply voltage and the control terminal of the buffer transistor being coupled to a reference terminal for receiving a reference voltage.

7. The amplifier circuit according to claim 1, wherein
the control block comprises a differential block having a first differential section for receiving a measure signal depending on the output signal, and a second differential section for receiving a target signal indicative of a target value of the measure signal, the first differential section and the second differential section cooperating for providing a control current defining the control signal according to a difference between the measure signal and the target signal, and wherein
the amplifier circuit comprises a further reference branch of a further current mirror coupled with the first differential section for providing the control current, and the regulation means comprises at least one further operating branch of the further current mirror each one coupled with a corresponding load node, and wherein
the second differential section of the control block comprises the buffer means, the buffer means providing the buffer current equal to the control current to each load node.

8. The amplifier circuit according to claim 7, wherein the buffer means comprises at least one buffer transistor having a first conduction terminal coupled with the first differential section for implementing a corresponding differential stage together with the first section, a second conduction terminal coupled to a respective load node and a control terminal for receiving the target signal.

9. The amplifier circuit according to claim 1, wherein the buffer means comprises at least one buffer transistor having a first conduction terminal, a second conduction terminal and a control terminal, the second conduction terminal of the buffer transistor being coupled with a corresponding load node, the first conduction terminal of the buffer transistor being coupled to a supply terminal for receiving a supply voltage and the control terminal of the buffer transistor being coupled to a reference terminal for receiving a reference voltage, and wherein the regulation means comprises
at least one first differential transistor each one having a first conduction terminal coupled to a corresponding load node, a second conduction terminal coupled to the second conduction terminal of a corresponding buffer transistor, and a control terminal for receiving the control signal, and
at least one second differential transistor each one having a first conduction terminal coupled to a corresponding load node, a second conduction terminal coupled with a corresponding output terminal, and a control terminal for receiving a reference signal, the regulation current depending on a difference between the control signal and the reference signal, and each buffer transistor providing the buffer current equal to the regulation current.

10. The amplifier circuit according to claim 1, wherein the amplifier circuit has a differential structure, the amplifier stage having a first input terminal and a second input terminal for receiving a first input signal and a second input signal, respectively, and a first output terminal and a second output terminal for providing a first output signal and a second output signal, respectively, each one having a common mode component and a complementary signal component, the amplifier stage having a first load node and a second load node being coupled with the first output terminal and the second output terminal, respectively, and the control block providing the control signal according to the common mode component of the output signal for regulating the common mode component of the output signal in feedback.

11. An electronic system comprising the amplifier circuit according to claim 1.

12. A method for operating an amplifier circuit comprising the steps of:
providing an input signal to at least one input terminal of an amplifier stage for obtaining an output signal being amplified with respect to the input signal at least one output terminal of the amplifier stage,
providing a control signal to a load stage of the amplifier stage according to the output signal for regulating the output signal in feedback, the load stage comprising at least one load node each one coupled with a corresponding one of the at least one output terminal,
providing a first bias current to each load node through the amplifier stage,
providing at least one second bias current to each load node, and
providing a regulation current to each load node according to the control signal
replicating the first bias current into a separation current,
sinking the separation current from each load node,
providing a buffer current to each load node, the buffer current balancing the at least one second bias current and the regulation current at each load node.
